(19) United States
(12) Patent Application Publication
(10) Pub. No.: US 2021/0336182 A1
(43) Pub. Date: Oct. 28, 2021

(54) OLED DISPLAY SUBSTRATE, MANUFACTURING METHOD THEREOF AND DISPLAY DEVICE

(71) Applicant: BOE TECHNOLOGY GROUP CO., LTD., Beijing (CN)

(72) Inventor: Fengjuan LIU, Beijing (CN)

(73) Assignee: BOE TECHNOLOGY GROUP CO., LTD., Beijing (CN)

(21) Appl. No.: 16/611,016

(22) PCT Filed: Mar. 28, 2019
(86) PCT No.: PCT/CN2019/080018

§ 371 Date: Nov. 5, 2019

(30) Foreign Application Priority Data
May 3, 2018 (CN) 201810413834.3

(51) Int. Cl. H01L 51/52; H01L 27/32; H01L 51/56

(52) U.S. Cl. CPC H01L 51/5209; H01L 27/3246; H01L 51/56; H01L 2227/323; H01L 2251/5307; H01L 51/5218; H01L 2251/5315

(57) ABSTRACT

The present disclosure provides an OLED display substrate, a manufacturing method thereof and a display device. The method for manufacturing an OLED display substrate includes: fabricating, a first conducting layer and a second conducting layer on a substrate, the first conducting layer being located between the second conducting layer and the substrate; fabricating a pixel definition layer on the second conducting layer, the pixel definition layer defining a plurality of open regions; performing a post-bake processing on the pixel definition layer; and removing portions of the second conductive layer at the open regions of the pixel definition layer to expose the first conductive layer under the second conductive layer.

### CROSS-REFERENCE TO RELATED APPLICATION

This application claims a priority to Chinese Patent Application No. 201810413834.3 filed in China on May 3, 2018, the disclosure of which is incorporated herein in its entirety by reference.

### TECHNICAL FIELD

The present disclosure relates to a field of a display technology, and in particular to an OLED display substrate, a manufacturing method thereof and a display device.

### BACKGROUND

In a process of manufacturing an OLED display substrate in the related art, firstly, a pattern of an anode layer is formed, then an organic Pixel Definition Layer (PDL) is fabricated, and a post-bake process of the pixel definition layer is performed, and finally a light emitting layer and a cathode layer are formed through evaporation.

### SUMMARY

The present disclosure provides a method for manufacturing an OLED display substrate, including:

fabricating, a first conducting layer and a second conducting layer on a substrate, the first conducting layer being located between the second conducting layer and the substrate;

fabricating a pixel definition layer on the second conducting layer, the pixel definition layer defining a plurality of open regions;

performing a post-bake processing on the pixel definition layer; and

removing portions of the second conductive layer at the open regions of the pixel definition layer to expose the first conductive layer under the second conductive layer.

Further, an etching selection ratio of the second conductive layer is larger than that of the first conductive layer.

Further, removing portions of the second conductive layer at the open regions of the pixel definition layer, comprises:

performing wet etching on the second conductive layer to remove a part of the second conductive layer exposed to the open regions.

Further, an etching solution for the wet etching is selected from acetic acid, nitric acid and phosphoric acid.

Further, an etching rate of the second conductive layer in the etching solution is at least 10 times of the etching rate of the first conductive layer in the etching solution.

Further, subsequent to removing portions of the second conductive layer at the open regions of the pixel definition layer, the method further includes:

forming a light emitting layer on the pixel definition layer and on portions of the first conductive layer exposed through the open regions of the pixel definition layer; and

fabricating a cathode layer on the light emitting layer.

Embodiments of the present disclosure also provide an OLED display substrate, including:

a substrate;

a thin film transistor layer formed on the substrate;

a first conducting layer formed on the thin film transistor layer;

a pixel definition layer formed on the first conducting layer, wherein the pixel definition layer comprises open regions and non-open regions, portions of the first conductive layer are exposed through the open regions of the pixel definition layer, and a second conductive layer is provided between the non-open region of the pixel definition layer and the first conductive layer in the non-open region;

a light emitting layer formed on the non-open region of the pixel definition layer and on portions of the first conductive layer exposed through the open region of the pixel definition layer; and

a cathode layer formed on the light emitting layer.

Further, the first conductive layer is made of transparent conductive material, and the second conductive layer is made of at least one of Mo and Al.

Embodiments of the present disclosure also provide a display device, including the OLED display substrate described above.

### BRIEF DESCRIPTION OF THE DRAWINGS

FIG. 1-FIG. 2 are schematic diagrams illustrating manufacturing an OLED display substrate in the related art;

FIG. 3 is a schematic diagram illustrating damage caused by a foreign body to a light emitting layer and a cathode layer in an OLED display substrate of the related art; and

FIG. 4-FIG. 6 are schematic diagrams illustrating manufacturing an OLED display substrate according to some embodiments of the present disclosure.

### DETAILED DESCRIPTION

In order to make an objective, a technical solution and an advantage of the present disclosure clearer, the embodiments of the present disclosure will be illustrated in detail hereinafter with reference to the accompanying drawings and specific embodiments.

It is founded that, in a post-bake process of a pixel definition layer, because an organic material is not completely solidified, a lot of gases and substances will be released and adsorbed in a post-bake chamber, so a cleanliness of the post-bake chamber of the organic material is relatively low. When a substrate is post-baked in the chamber, some foreign bodies will inevitably fall on the substrate. Since the size of the foreign body is relatively small, it cannot be completely removed by cleaning. In a subsequent process of evaporating a light emitting layer and a cathode layer, the foreign body will remain in the light emitting layer. In a process of cover plate packaging and cell alignment of the OLED display substrate, the foreign body will cause damage to the light emitting layer and the cathode layer, resulting in a display Mura (such as a bright spot, a black spot, a black patch, etc.) phenomenon, affecting a display quality of a display device.

A technical problem to be solved by the present disclosure is to provide an OLED display substrate, a manufacturing method thereof and a display device, which may remove residual foreign bodies on an anode layer, prevent appearance of a display Mura phenomenon and improve a display quality of the display device.

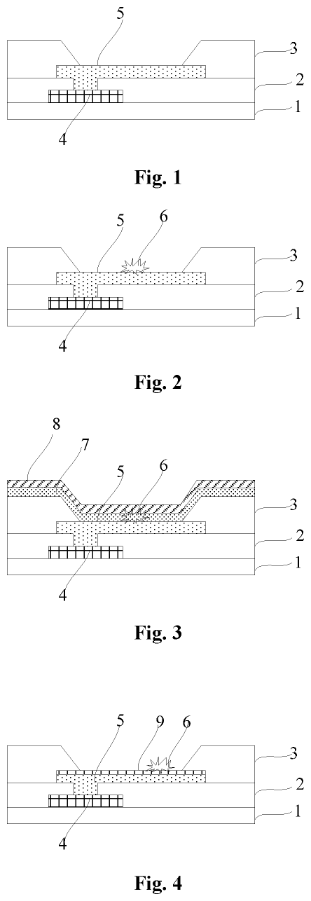

FIG. 1-FIG. 2 are schematic diagrams illustrating manufacturing an OLED display substrate in the related art. In a process of manufacturing the OLED display substrate in the related art, firstly, a pattern of a first conductive layer 5 is formed on a substrate 1 where a thin film transistor 4 and a planarization layer 2 are formed, then an organic pixel definition layer 3 is fabricated, then a post-bake process of the pixel definition layer 3 is performed, and finally a light emitting layer 7 and a cathode layer 8 are formed through evaporation. In a post-bake process of the pixel definition layer 3, because an organic material is not completely solidified, a lot of gases and substances will be released and adsorbed in a post-bake chamber, so a cleanliness of the post-bake chamber of the organic material is relatively low. When a substrate is post-baked in the chamber, some foreign bodies 6 will inevitably fall on the substrate. A size of the foreign body 6 is relatively small, and it cannot be completely removed by cleaning. Subsequently, an Electronic Parameter Measurement (EPM) characteristic test is performed on the substrate to monitor a backplane characteristic. Finally, an evaporation process of the light emitting layer 7 and the cathode layer 8 is performed in an evaporation device. As shown in FIG. 3, in a subsequent evaporation process of the light emitting layer 7 and the cathode layer 8, the foreign body 6 will remain in the light emitting layer 7. In a process of cover plate packaging and cell alignment of the OLED display substrate, the foreign body 6 will cause damage to the light emitting layer 7 and the cathode layer 8, and the light emitting layer 7 may show poor luminescence at the location of the foreign bodies and diffuse around the foreign bodies, resulting in a display Mura (such as a bright spot, a black spot, a black patch, etc.) phenomenon, affecting a display quality of a display device.

In order to solve the above problems, embodiments of the present disclosure provide an OLED display substrate, a manufacturing method thereof and a display device, which may remove residual foreign bodies on the anode layer, prevent appearance of a display Mura phenomenon and improve a display quality of the display device.

Embodiments of the present disclosure provide a method for manufacturing an OLED display substrate, including:

fabricating a first conducting layer and a second conducting layer on a substrate, the first conducting layer being located between the second conducting layer and the substrate;

fabricating a pixel definition layer on the substrate, the pixel definition layer includes the first conducting layer and the second conducting layer and defines a plurality of open regions; and

removing portions of the second conductive layer exposed to the open region after a post-bake process of the pixel definition layer is completed.

In the embodiments of the present disclosure, before fabricating the pixel definition layer, the first conducting layer and the second conducting layer are fabricated, and after completing a post-bake process of the pixel definition layer, the second conductive layer exposed to the open region is removed, so that foreign bodies may be also removed while removing the second conductive layer, even if the foreign bodies fall on the second conductive layer in the post-bake process. Therefore, damage caused by the foreign bodies to the light emitting layer and the cathode layer may be prevented, an appearance of a display Mura phenomenon may be avoided, and a display quality and reliability of the display device may be improved.

Further, an etching selection ratio of the second conductive layer is larger than that of the first conductive layer, so that the etching solution has less influence on the first conductive layer when the second conductive layer is removed by using the etching solution.

Unless defined otherwise, a term “the first conductive layer” in the present disclosure refers to the anode layer in an OLED construction. The second conductive layer refers to a film layer additionally arranged on the first conductive layer (the anode layer) in the present disclosure; after the post-bake process of the pixel definition layer, a part of the second conductive layer at the open regions of the pixel definition layer will be removed by, for example, a wet etching process, thereby the foreign bodies dropped on the second conductive layer may be removed together, which may eliminate the problem of poor display resulted from the dropped foreign bodies during the post-bake process.

In the embodiments described later with reference to the accompanying drawings, terms “first conductive layer” and “anode layer” may be used interchangeably. The first conductive layer may be a multi-layer structure with two or more layers, and the second conductive layer may be a multi-layer structure with two or more layers. The OLED display substrate manufactured in the present disclosure may be a top-emitting OLED display substrate or a bottom-emitting OLED display substrate.

When the OLED display substrate is the bottom-emitting OLED display substrate, since an anode layer of the bottom-emitting OLED display substrate is required to be transparent, after removing the second conductive layer, the remaining first conductive layer will constitute the anode layer of a final OLED display substrate, the first conductive layer may be made of a transparent conductive material including Indium Tin Oxide (ITO), InOx, etc. In some embodiments, the second conductive layer may be made of at least one of, for example, Mo and Al, so that the etching selection ratio of the second conductive layer is larger than that of the first conductive layer, and the etching solution has less influence on the first conductive layer when the second conductive layer is removed by using the etching solution.

When the OLED display substrate is the top-emitting OLED display substrate, in general, an anode layer may be a composite anode layer including a reflective electrode layer with a high reflectivity and a matched work function with a high transparency, such as ITO, InOx, etc. For example, the composite anode layer may be ITO/Ag/ITO, ITO/material of Al series/ITO. After removing the second conductive layer, the remaining first conductive layer will constitute the anode layer of a final OLED display substrate, the first conductive layer may be made of a composite anode layer including a reflective electrode layer with a high reflectivity and a matched work function with a high transparency, such as ITO, InOx, etc. The second conductive layer may be made of at least one of, for example, Mo and Al, so that the etching selection ratio of the second conductive layer is larger than that of the first conductive layer, and the etching solution has less influence on the first conductive layer when the second conductive layer is removed by using the etching solution.

Further, the process of removing portions of the second conductive layer at the open regions after completing a post-bake process of the pixel definition layer, includes:

performing wet etching on the second conductive layer to remove a part of the second conductive layer exposed to the open regions.

According to some embodiments of the present disclosure, a solution of the wet etching is selected from acetic acid, nitric acid and phosphoric acid.

Optionally, an etching rate of the second conductive layer in the etching solution is more than 10 times that of the first conductive layer in the etching solution, thus the etching solution has less influence on the first conductive layer when the second conductive layer is removed by the etching solution, and a performance of the anode layer may be ensured.

Further, the method further includes:

after removing the second conductive layer exposed to the open regions,

fabricating a light emitting layer and a cathode layer on the light emitting layer successively.

The light emitting layer may be fabricated by evaporation or printing, and the cathode may be fabricated by evaporation or sputtering.

Since the second conductive layer has been removed, there will be no foreign bodies in the anode layer, and there will be no foreign bodies remaining in the light emitting layer.

In the above solution, before fabricating the pixel definition layer, the first conducting layer and the second conducting layer are fabricated, and after a post-bake process of the pixel definition layer is completed, the second conductive layer exposed to the open regions of the pixel definition layer is removed, so that foreign bodies may be also removed while removing the second conductive layer, even if the foreign bodies fall on the second conductive layer in the post-bake process. Therefore, damage caused by the foreign bodies to the light emitting layer and the cathode layer may be prevented, an appearance of a display Mura phenomenon may be avoided, and a display quality and reliability of the display device may be improved.

The method for manufacturing an OLED display substrate in the present disclosure will be illustrated hereinafter with reference to the accompanying drawings, according to some embodiments of the present disclosure, the method for manufacturing the OLED display substrate includes following steps.

Step 1, forming patterns of a first conducting layer and a pattern of a second conducting layer on a substrate.

In some embodiments, a thin film transistor 4 and a planarization layer 2 are fabricated on a substrate 1, and then a first conductive layer 5 and a second conductive layer 9 are formed on a film layer including the thin film transistor 4. The first conductive layer 5 is connected with a drain electrode of the thin film transistor 4 by a hole through the planarization layer 2. According to some embodiments of the present disclosure, a layer of a transparent conductive material and a layer of a conductive material may be formed successively on the substrate, the transparent conductive material may be made of ITO or IZO, and the conductive material may be made of Mo or Al. Photoresist is coated on the conductive material and exposed by using a mask. After developing, photoresist removing regions and photoresist residual regions are formed. The conductive materials and the transparent conductive materials in the photoresist removing regions are etched, and required patterns of the first conductive layer 5 and the second conductive layer 9 are formed. The etching selection ratio of the transparent conductive material is larger than that of the conductive material. When etching the conductive material and the transparent conductive material, two different etching solutions may be used for etching the conductive material and the transparent conductive material respectively.

Step 2, forming patterns of the pixel definition layer on the substrate after step 1.

According to some embodiments of the present disclosure, a layer of a pixel definition layer material may be formed on the substrate. The pixel definition layer material may be an organic material. The photoresist is coated on the pixel definition layer material and exposed with a mask. After developing, photoresist removing regions and photoresist residual regions are formed. The pixel definition layer material in the photoresist removing regions is etched, and patterns of the pixel definition layer 3 are formed. The patterns of the pixel definition layer 3 define open regions.

Step 3, performing a post-bake processing on the patterns of the pixel definition layer 3.

After step 2, the substrate is moved into a post-bake chamber, and a post-bake process of the pixel definition layer 3 is performed, as shown in FIG. 4. Since a cleanliness of the post-bake chamber is relatively low, when the substrate is post-baked in the chamber, foreign bodies 6 will inevitably fall on the substrate. According to the embodiments of the present disclosure, by setting the second conductive layer 9 on the first conductive layer 5, the foreign bodies 6 fall on the second conductive layer 9 in the post-bake process.

Step 4, removing the second conductive layer 9 exposed to the open regions by wet etching.

Photoresist is coated on the substrate of the step 3 and exposed with a mask. After developing, photoresist removing regions and photoresist residual regions are formed. The photoresist removing regions corresponds to the open regions, the second conductive layer 9 of the photoresist removing regions is etched with an etching solution. The solution of the wet etching is selected from acetic acid, nitric acid and phosphoric acid. As shown in FIG. 5, while the second conductive layer 9 is removed, the foreign body 6 on the second conductive layer 9 will also be removed.

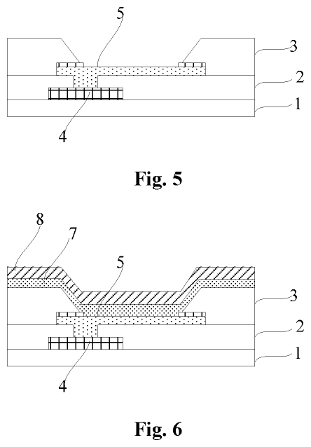

Step 5, as shown in FIG. 6, evaporating a light emitting layer 7 and a cathode layer 8 are formed by evaporation on the substrate after step 4 is completed.

A process of evaporating the light emitting layer 7 and the cathode layer 8 is similar to the related art, which will not be repeated here.

In the embodiments, after completing a post-bake process of the pixel definition layer, the conductive layer exposed to the open regions may be removed before evaporating the light emitting layer 7 and the cathode layer 8. Thus, the foreign bodies may also be removed while removing the conductive layer without affecting the characteristic test, even if the foreign bodies fall on the conductive layer in the post-bake process. Therefore, damage caused by the foreign bodies to the light emitting layer and the cathode layer may be prevented, an appearance of a display Mura phenomenon may be avoided, the OLED display substrate may achieve good luminescent effect, and a display quality and reliability of the display device may be improved.

Embodiments of the present disclosure further provide an OLED display substrate manufactured by the method described above.

In the OLED display substrate of the embodiment, before fabricating the pixel definition layer, the first conducting layer and the second conducting layer are fabricated, and after completing a post-bake process of the pixel definition layer, the second conductive layer exposed to the open regions is removed, so that the foreign bodies may also be removed while removing the second conductive layer, even if the foreign bodies fall on the second conductive layer in the post-bake process. Therefore, there will be no foreign bodies remaining in the light emitting layer of the OLED display substrate, an appearance of a display Mura phenomenon may be avoided, and a display quality and reliability of the display device may be improved.

The embodiments of the present disclosure further provide a display device including the OLED display substrate described above. The display device may be any product or component with display function, such as TV, display, digital photo frame, mobile phone, tablet computer, etc. The display device also includes a flexible circuit board, a printed circuit board and a backplane.

In the embodiments of the present disclosure, before fabricating the pixel definition layer, the first conducting layer and the second conducting layer are fabricated, after completing a post-bake process of the pixel definition layer, the second conductive layer exposed to the open regions is removed, so that the foreign bodies may also be removed while removing the second conductive layer, even if the foreign bodies fall on the second conductive layer in the post-bake process. Therefore, there will be no foreign bodies remaining in the light emitting layer of the display device, an appearance of a display Mura phenomenon may be avoided, and a display quality and reliability of the display device may be improved.

In each method embodiment of the present disclosure, sequence numbers of the steps described cannot be used for defining the sequence of the steps. For those skilled in the art, the sequence changes of the steps without any creative work are also within the protection scope of the present disclosure.

Unless defined otherwise, technical or scientific terms in the embodiments of the present disclosure shall be of general meanings understood by those skilled in the art. Terms “first”, “second” and similar terms in the embodiments of the present disclosure do not indicate any order, quantity or importance, but are used only for distinguishing different components. A term “include”, “comprise” or other term with similar meaning indicates that components or objects before the term cover components, objects or other equivalents listed after the term, instead of excluding other components or objects. A term “connect”, “attach” or other term with similar meaning is not limited to a physical connection or a mechanical connection, but may include an electrical connection, whether direct or indirect. “Up”, “down”, “left”, “right” and so on are only used to represent a relative position relationship. When an absolute position of an object is changed, the relative position relationship may also change accordingly.

It is understandable that when a component such as a layer, film, region or substrate is said to be located “above” or “below” another component, the component may be “directly” located “above” or “below” another component, or intermediate components may exist.

The embodiments described above are optional embodiments of the present disclosure, and it should be pointed out that those skilled in the art may make various modifications and changes without departing from the spirit and the scope of the present disclosure. The modifications and changes shall also be regarded as the protection scope of the present disclosure.

1. A method for manufacturing an OLED display substrate, comprising:
fabricating a first conducting layer and a second conducting layer on a substrate, the first conducting layer being located between the second conducting layer and the substrate;
fabricating a pixel definition layer on the second conducting layer, the pixel definition layer defining a plurality of open regions;
performing a post-bake processing on the pixel definition layer; and
removing portions of the second conductive layer at the open regions of the pixel definition layer to expose the first conductive layer under the second conductive layer.

2. The method according to claim 1, wherein an etching selection ratio of the second conductive layer is larger than that of the first conductive layer.

3. The method according to claim 2, wherein removing portions of the second conductive layer at the open regions of the pixel definition layer comprises:
performing wet etching on the second conductive layer to remove a part of the second conductive layer exposed to the open regions.

4. The method according to claim 3, wherein an etching solution for the wet etching is selected from acetic acid, nitric acid and phosphoric acid.

5. The method according to claim 4, wherein an etching rate of the second conductive layer in the etching solution is at least 10 times of the etching rate of the first conductive layer in the etching solution.

6. The method according to claim 1, wherein subsequent to removing portions of the second conductive layer at the open regions of the pixel definition layer, the method further comprises:
forming a light emitting layer on the pixel definition layer and on portions of the first conductive layer exposed through the open regions of the pixel definition layer, and
fabricating a cathode layer on the light emitting layer.

7. The method according to claim 1, wherein prior to fabricating the first conducting layer and the second conducting layer on a substrate, the method further comprises:
forming a thin film transistor layer on the substrate.

8. An OLED display substrate, comprising:
a substrate;
a thin film transistor layer formed on the substrate;
a first conducting layer formed on the thin film transistor layer;
a pixel definition layer formed on the first conducting layer, wherein the pixel definition layer comprises open regions and non-open regions, portions of the first conductive layer are exposed through the open regions of the pixel definition layer, and a second conductive layer is provided between the non-open region of the pixel definition layer and the first conductive layer;
a light emitting layer formed on the non-open region of the pixel definition layer and on portions of the first conductive layer exposed through the open region of the pixel definition layer; and
a cathode layer formed on the light emitting layer.

9. The OLED display substrate according to claim 8, wherein the first conductive layer is made of transparent conductive material, and the second conductive layer is made of at least one of Mo and Al.

10. A display device, comprising the OLED display substrate according to claim 8.

11. The display device according to claim 10, wherein the first conductive layer is made of transparent conductive material, and the second conductive layer is made of at least one of Mo and Al.
